(19) United States
(12) Patent Application Publication
(10) Pub. No.: US 2009/0120674 A1
(43) Pub. Date: May 14, 2009

(54) BUILT-IN BATTERY ASSEMBLY AND A METHOD OF ASSEMBLING THE BUILT-IN BATTERY WITH A CIRCUIT BOARD

(75) Inventor: Ming-Shiung Chang, Tu-Cheng (TW)

Correspondence Address: PCE INDUSTRY, INC.;ATT. Steven Reiss, 458 E. LAMBERT ROAD, FULLERTON, CA, 92835, US

(73) Assignee: CHI MEI COMMUNICATION SYSTEMS, INC., Tu-Cheng City (TW)

(21) Appl. No.: 12/164,242

(22) Filed: Jun. 30, 2008

(30) Foreign Application Priority Data
Nov. 14, 2007 (CN) 200710202527.2

(51) Int. Cl. H05K 1/16; H05K 1/00; H05K 3/30

(52) U.S. Cl. 174/260; 361/748; 29/832

(57) ABSTRACT

A built-in battery assembly (100) including a battery body (10) and a flexible connecting board (50) is described. The flexible connecting board includes a first pair of terminals (52) and a second pair of terminals (55), wherein the first pair of terminals electrically connects to the battery body and the second pair of terminals protrudes from the battery body. In addition, a method of assembling the built-in battery assembly to a circuit board (80) is also described.

### BACKGROUND OF THE INVENTION

1. Field of the Invention

The present invention generally relates to built-in batteries and, particularly, to built-in batteries arranged within a portable electronic device and a method of assembling the built-in battery assembly to a circuit board of the portable electronic device.

2. Discussion of the Related Art

With rapid development of communication, portable electronic devices, such as cellular phones, personal digital assistant (PDA), and so on, have become more and more popular. Generally, the portable electronic devices are equipped with detachable batteries. However, as the demand for light and small portable electronic devices increases, built-in batteries are provided that reduce the required internal space for electronic elements in the portable electronic devices.

Conventional built-in batteries have positive and negative poles, and the output end of the positive and negative poles are drawn out via two leading wires welded thereon. In addition, a connector is applied for electrically connecting the built-in battery and a circuit board together to supply power to the portable electronic devices. However, the connector not only takes up space, but also increases overall cost of the portable electronic devices. Further, according to typical manufacturing process, the two leading wires are manually welded, thereby significantly affecting assembly efficiency. Moreover, the above welding process may damage electronic elements or antennas arranged within the portable electronic devices, thereby affecting the performance of the portable electronic devices.

Therefore, a new built-in battery assembly is desired that not only can be easily assembled with a circuit board of the portable electronic device but also can prevent the portable electronic devices from interference. In addition, a method of assembling the built-in battery assembly with a circuit board of portable electronic devices is also desired.

### BRIEF DESCRIPTION OF THE DRAWINGS

Many aspects of the built-in battery assembly can be better understood with reference to the following drawings. The components in the drawings are not necessarily to scale, the emphasis instead being placed upon clearly illustrating the principles of the present built-in battery assembly. Moreover, in the drawings, like reference numerals designate corresponding parts throughout the several views.

FIG. 1 is an exploded, isometric view of the built-in battery assembly according to an exemplary embodiment.

FIG. 2 is an isometric view of the built-in battery assembly in FIG. 1.

FIG. 3 is an assembled, isometric view of the built-in battery assembly in FIG. 2.

FIG. 4 is an isometric view illustrating the first step of the method of assembling the built-in battery assembly in FIG. 3 with a circuit board.

FIG. 5 is an isometric view illustrating the second step of the method of assembling the built-in battery assembly in FIG. 3 with the circuit board.

FIG. 6 is an isometric view illustrating the third step of the method of assembling the built-in battery assembly in FIG. 3 with the circuit board.

### DETAILED DESCRIPTION OF THE EMBODIMENTS

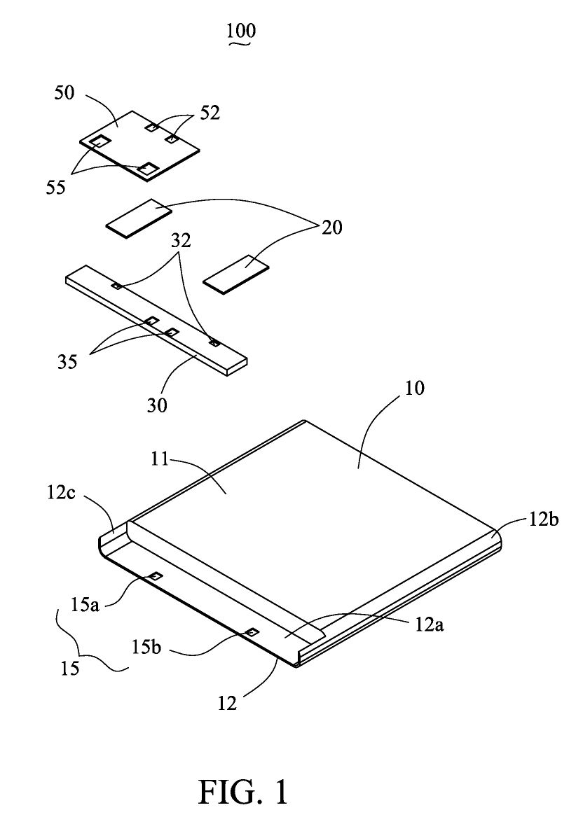

FIG. 1 shows an exemplary embodiment of a built-in battery assembly 100 including a battery body 10, two connecting strips 20, a protective circuit board 30 and a flexible connecting board 50. The battery body 10 is substantially rectangular-shaped and includes a main body 11, a receiving portion 12, and a positive pole 15a and a negative pole 15b. The main body 11 is substantially rectangular-shaped. The receiving portion 12 is formed by a base 12a and two vertical opposite sides 12b, 12c. As shown in FIG. 1, the receiving portion 12 has a U-shaped cross-section. The main body 11 may be arranged within the receiving portion 12. The positive pole 15a and the negative pole 15b of the battery body 10, which are spaced from each other, are associated with the base 12a of the receiving portion 12.

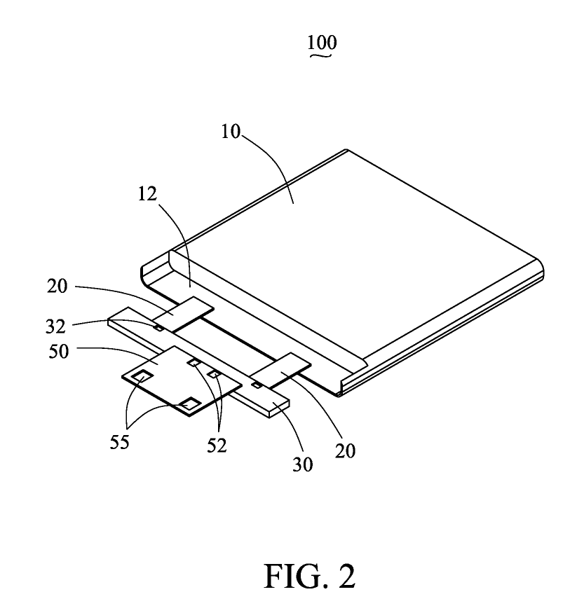

The two connecting strips 20 are made of flexible conductive material. Referring to FIG. 2, each connecting strip 20 electrically connects one of the positive pole 15a and the negative pole 15b, to the protective circuit board 30.

The protective circuit board 30 is a substantially rectangular-shaped printed circuit board with at least one protective circuit arranged thereon for preventing the battery body 10 from being overcharged or overheated. The protective circuit board 30 includes a surface having a pair of feed points 32 arranged on one side and a pair of output points 35 arranged on an opposite side. The distance between the feed points 32 is equal to the distance between the positive pole 15a and the negative pole 15b so that the pair of feed points 32 electrically connects with the battery body 10 by the two connecting strips 20 without twisting the connecting strips 20. In addition, the protective circuit board 30 electrically connects with the flexible connecting board 50 by the pair of the output points 35.

The flexible connecting board 50 includes a first pair of terminals 52 and a second pair of terminals 55 that are oppositely arranged on two ends of the flexible connecting board 50. The first pair of terminals 52 electrically connects with the pair of output points 35 of the protective circuit board 30, and the second pair of terminals 55 electrically connects to a circuit board of an electronic device.

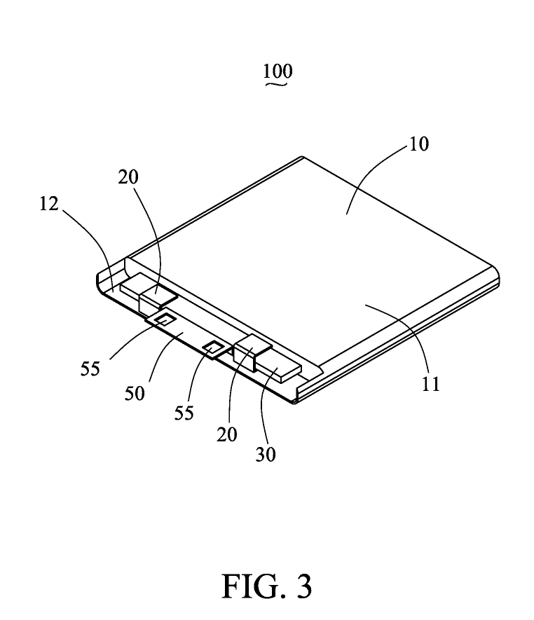

Referring to FIG. 3, the battery body 10, the connecting strips 20, the protective circuit board 30, the flexible connecting board 50 are assembled according to the above connective relationship. When assembled, the two connecting strips 20 are bent back toward the battery body 10, and the protective circuit board 30, connected to the two connecting strips 20, is thus rotated approximately 180 degrees. Therefore, the protective circuit board 30 and the flexible connecting board 50 are received within the receiving portion 12. Afterwards, the second pair of terminals 55 protrudes out from the receiving portion 12 of the battery body 10 as shown in FIG. 3. Understandably, the first connecting end 52 electrically connects to the battery body 10 using the protective circuit board 30 and the two connecting strips 20. The bending method of the flexible connecting board 50 is not limited to the above bending method of the embodiment. That is, any bending method may be applied as long as the second pair of terminals 55 of the flexible connecting board 50 can contact and be electrically connected to the other circuit boards.

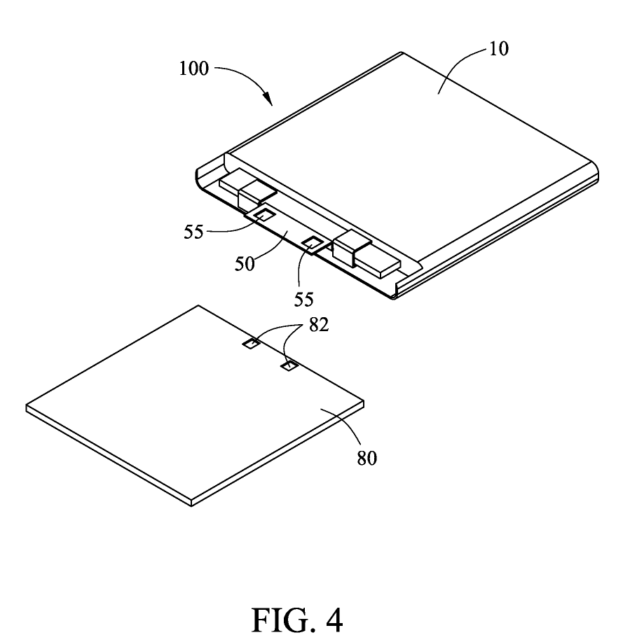

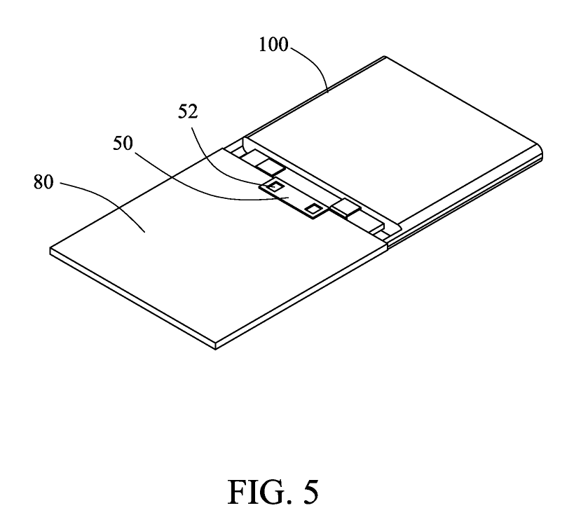

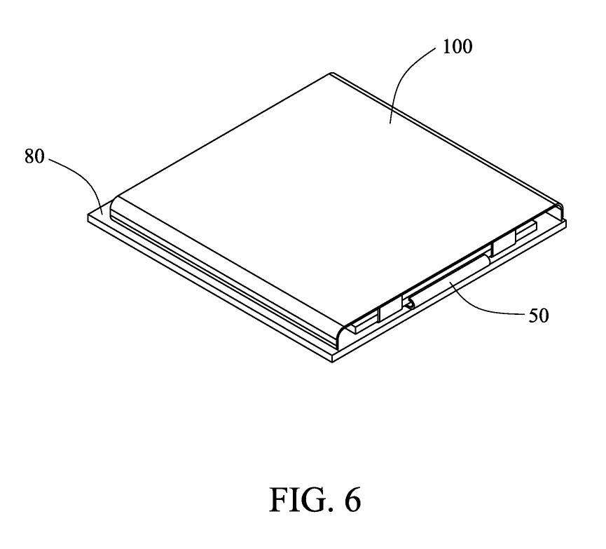

FIGS. 4 to 6 show the method of assembling the built-in battery assembly 100 with a circuit board 80. The circuit board 80 includes a pair of pads 82 arranged on one side of the circuit board 80. The pair of connecting pads 82 is configured for being electrically connecting to the second pair of terminals 55. In FIG. 5, the second pair of terminals 55 of the flexible connecting board 50 is aligned with the pair of connecting pad 82 of the circuit board 80. Afterwards, the second pair of terminals 55 is directly heated by a thermal press machine to weld the second pair of terminals 55 to the circuit board 80. Finally, the built-in battery assembly 100 is rotated relative to the circuit board 80 approximately 180 degrees thereby attaching the built-in battery assembly 100 to the circuit board 80 (FIG. 6).

With the above assembling method, the built-in battery assembly 100 is directly attached to the circuit board 80 without reserving additional space for the typical connector. Therefore, the space for receiving the circuit board 80 of the portable electronic device is reduced, and the overall cost of the portable electronic device is reduced simultaneously. Also, the flexible connecting board 50 may be welded with the circuit board 80 by a thermal press machine thereby improving the assembly process of the portable electronic devices. Moreover, the above welding processing also reduces the interference for electronic elements within the portable electronic device.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A built-in battery assembly, comprising:
a battery body; and
a flexible connecting board with a first pair of terminals and a second pair of terminals, wherein the first pair of terminals electrically connects to the battery body and the second pair of terminals protrudes from the battery body.

2. The built-in battery assembly as claimed in claim 1, wherein the built-in battery assembly includes a protective circuit board for electrically connecting the battery body to the flexible connecting board.

3. The built-in battery assembly as claimed in claim 2, wherein the battery body comprises a main body, a positive pole and a negative pole, and a receiving portion, and the positive and negative poles are arranged on the receiving portion.

4. The built-in battery assembly as claimed in claim 3, wherein the built-in battery assembly includes two connecting strips, each connecting strip connecting one of the positive and negative poles of the battery body to the protective circuit board.

5. The built-in battery assembly as claimed in claim 4, wherein the protective circuit board is a substantially rectangular-shaped board with a pair of feed points and a pair of output points, the pair of feed points electrically connects with the two connecting strips and the pair of output points electrically connects with the flexible connecting board.

6. The built-in battery assembly as claimed in claim 5, wherein the first pair of terminals electrically connects with the pair of output points of the protective circuit board, and the second pair of terminals is for electrically connecting a circuit board of an electronic device.

7. The built-in battery assembly as claimed in claim 4, wherein the two connecting strips are made of flexible conductive material.

8. The built-in battery assembly as claimed in claim 2, wherein the protective circuit board is a printed circuit board with at least one protective circuit arranged thereon for preventing the battery from being overcharged or overheated.

9. A method of assembling a built-in battery assembly to a circuit board, comprising:
providing a built-in battery assembly including a battery body and a flexible connecting board having first and second pairs of terminals;
connecting the battery body to the flexible connecting board using the first pair of terminals;
allowing the second pair of terminals to protrude from the battery body;
providing a circuit board;
welding the second pair of terminals of the flexible connecting board to a pair of pads of the circuit board; and
rotating the built-in battery assembly relative to the circuit board by about 180 degrees, thereby attaching the built-in battery assembly to the circuit board.

10. The method as claimed in claim 9, wherein the second pair of terminals is heated by a thermal press machine.

11. The method as claimed in claim 9, wherein the welding step is performed by directly heating the second pair of terminals.
